(19) United States
(12) Patent Application Publication
(10) Pub. No.: US 2025/0299739 A1
(43) Pub. Date: Sep. 25, 2025

(54) NONVOLATILE MEMORY WITH FAST PROGRAM VOLTAGE RAMP DOWN

(71) Applicant: Western Digital Technologies, Inc., San Jose, CA (US)

(72) Inventors: Xiaojia Jia, Santa Clara, CA (US); Yanwei He, Fremont, CA (US); Sarath Puthenthermadam, San Jose, CA (US); Zhixin Cui, Fremont, CA (US); Guirong Liang, Santa Clara, CA (US)

(73) Assignee: Western Digital Technologies, Inc., San Jose, CA (US)

(21) Appl. No.: 18/614,774

(22) Filed: Mar. 25, 2024

(51) Int. Cl. G11C 16/10; G11C 16/12; G11C 16/32

(52) U.S. Cl. CPC G11C 16/102; G11C 16/12; G11C 16/32

(57) ABSTRACT

An apparatus includes control circuits configured to connect to nonvolatile memory cells. The control circuits are configured to program the plurality of nonvolatile memory cells by applying program pulses at corresponding program voltages on control gates of the nonvolatile memory cells. One or more of the program pulses ends in a fast ramp-down from the corresponding program voltage to an offset target voltage that is offset from a post-pulse voltage by a negative kick voltage.

### BACKGROUND

The present technology relates to non-volatile memory and program operations for programming non-volatile memory cells.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be three-dimensional. One type of three-dimensional structure has non-volatile memory cells arranged as vertical NAND strings. The memory structure may be arranged into units that are commonly referred to as blocks. For example, a block in a NAND memory system contains many NAND strings. A NAND string contains memory cell transistors connected in series, a drain side select gate at one end, and a source side select gate at the other end. Each NAND string is associated with a bit line. The block typically has many word lines that provide voltages to the control gates of the memory cell transistors. In some architectures, each word line connects to the control gate of one memory cell on each respective NAND string in the block.

The non-volatile memory cells may be programmed to store data. Typically, the memory cells are programmed to a number of data states. Using a greater number of data states allows for more bits to be stored per memory cell. For example, four data states may be used to store two bits per memory cell, eight data states may be used in order to store three bits per memory cell, 16 data states may be used to store four bits per memory cell, etc. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 3 shows an example of a portion of a memory structure.

FIGS. 4A-G illustrate an example of a memory structure.

FIGS. 5A and 5B depict threshold voltage distributions.

FIG. 6 shows an example of applying program pulses at corresponding (increasing) program voltages in a program operation.

FIG. 7 shows an example of a program pulse of a program operation.

FIGS. 8A-B illustrate an example of disturbance of programmed data.

FIG. 9 illustrates overlap of threshold voltage distributions caused by disturbance.

FIG. 10 illustrates an example of a program pulse with different delay times from initiating discharge of the program pulse to initiating discharge of other components.

FIG. 11 illustrates an example of a program pulse with a negative kick.

FIGS. 12A-B illustrate different negative kick voltages.

FIGS. 13A-C illustrate a scheme for applying techniques to mitigate disturbance.

FIGS. 14A-B illustrate aspects of a method according to examples of the present technology.

### DETAILED DESCRIPTION

Technology is disclosed herein for reducing disturbance of programmed data when performing program operations. An example of disturbance may be caused by inadequate discharge of a selected word line at the end of a program pulse so that the selected WL may be at a relatively high voltage when channel cutoff occurs (e.g., due to previously programmed memory cells having high threshold voltages that turn off as unselected word lines discharge). This problem may occur in particular circumstances (e.g., only for relatively high program pulses and/or at particular locations such as particular dies, blocks, WLs). In an example, different delay times are used to ensure adequate discharge before channel cutoff (e.g., delay time from initiation of selected WL discharge to initiation of unselected WL discharge may be increased by an offset time for some pulses (e.g., relatively high voltage pulses) and/or according to location. In an example, fast ramp-down at the end of a program pulse is provided by using a negative kick voltage (e.g., using a voltage setpoint that is below a post-pulse voltage to cause selected WL voltage to dip below the post-pulse voltage). These techniques may be used separately or may be combined.

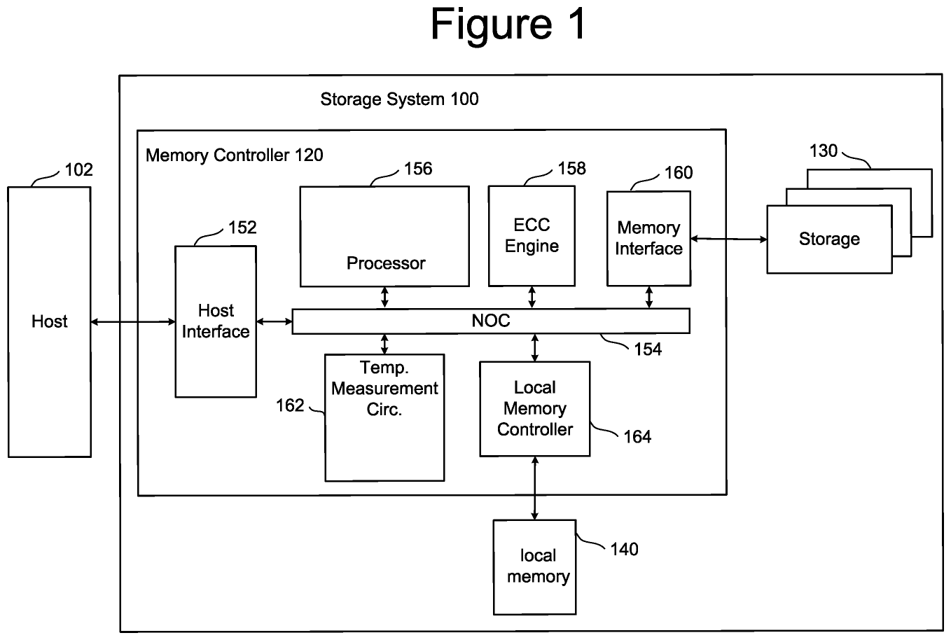

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of memory controller 120) implements a scheduler and buffer for transmitting data to and receiving data from one or more memory die.

Temperature measurement circuit 162 includes temperature transducer 163 located in memory controller 120 (e.g., formed in a memory controller die). Temperature measurement circuit 162 may generate temperature measurement values from temperature sensing by transducer 163 (e.g., from measurement of a current, voltage, resistance or other metric or some combination of metrics).

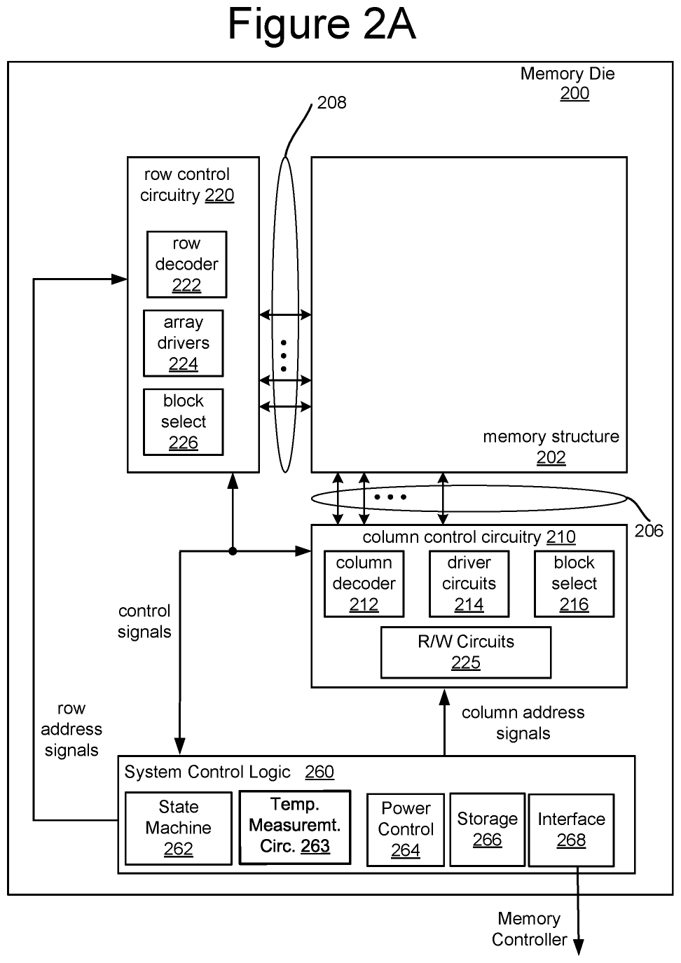

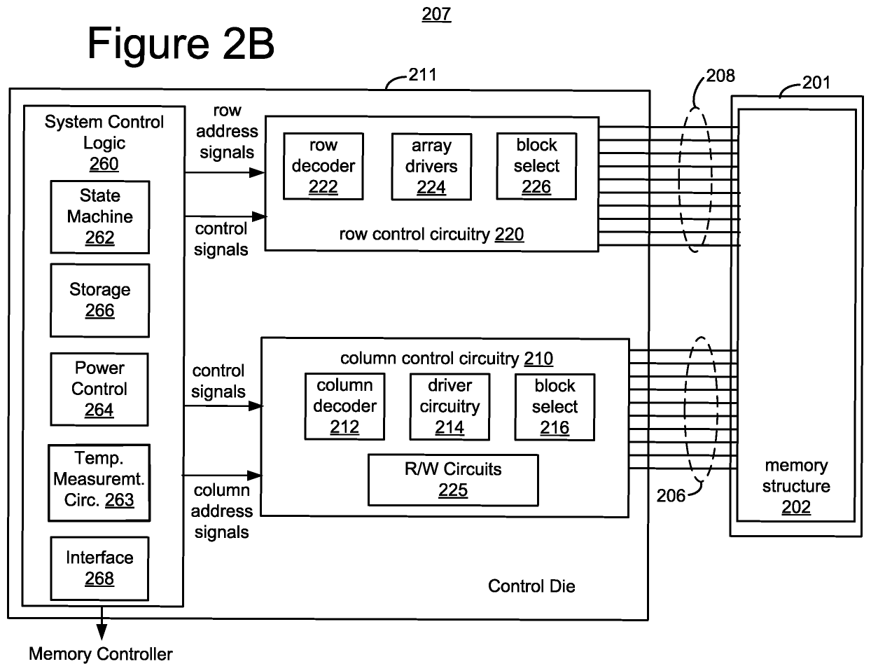

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202. Temperature measurement circuit 263 may generate temperature measurement values from temperature sensing by one or more temperature transducers located in memory die 200. Temperature measurement values obtained by temperature measurement circuit 263 may be used by system control logic 260, read/write circuits 225 and/or other components to apply temperature adjustment according to on-chip temperature. Temperature measurement circuit 263 may be provided instead of or in addition to temperature measurement circuit 162.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

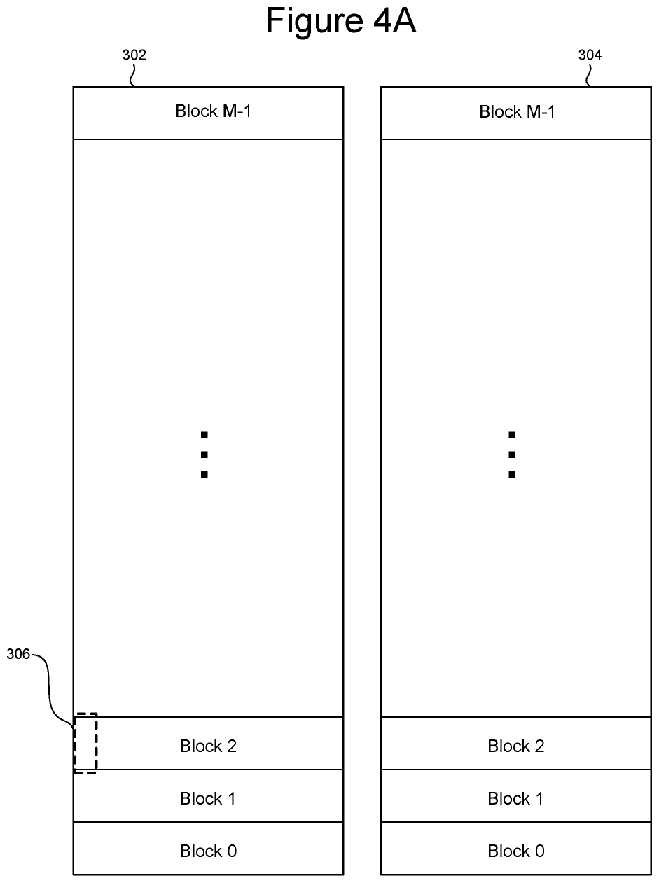

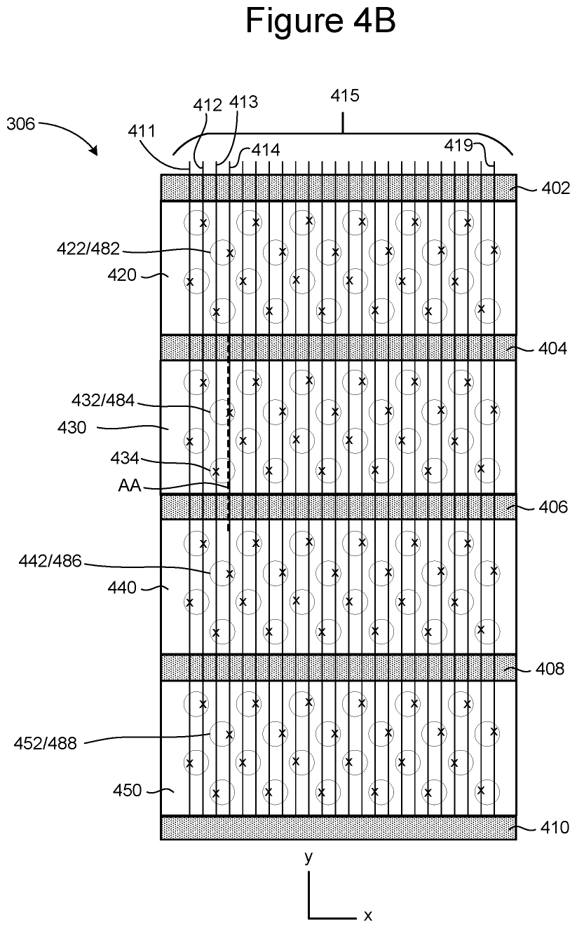

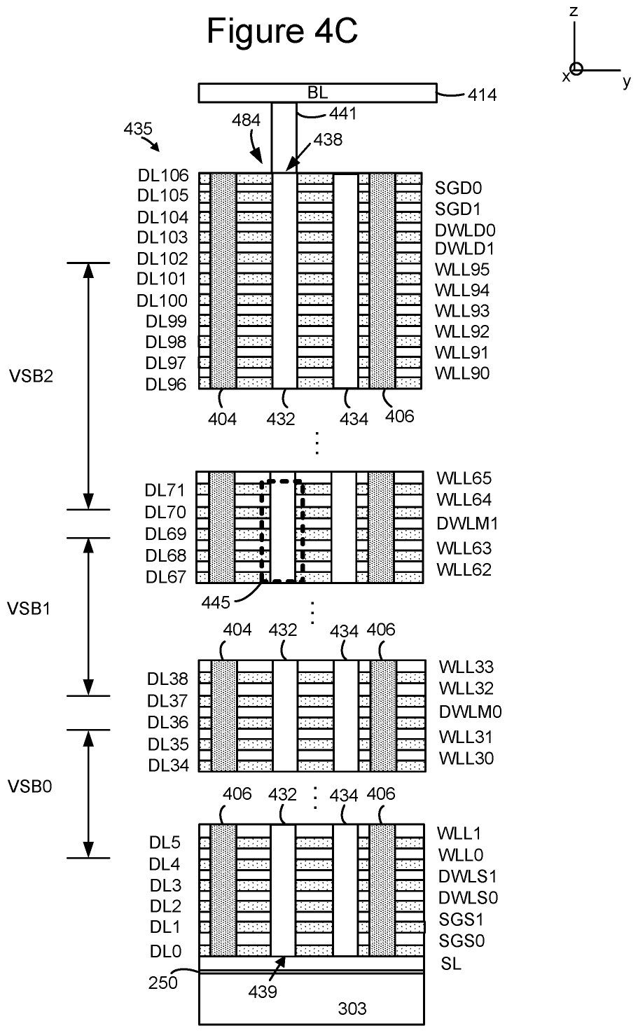

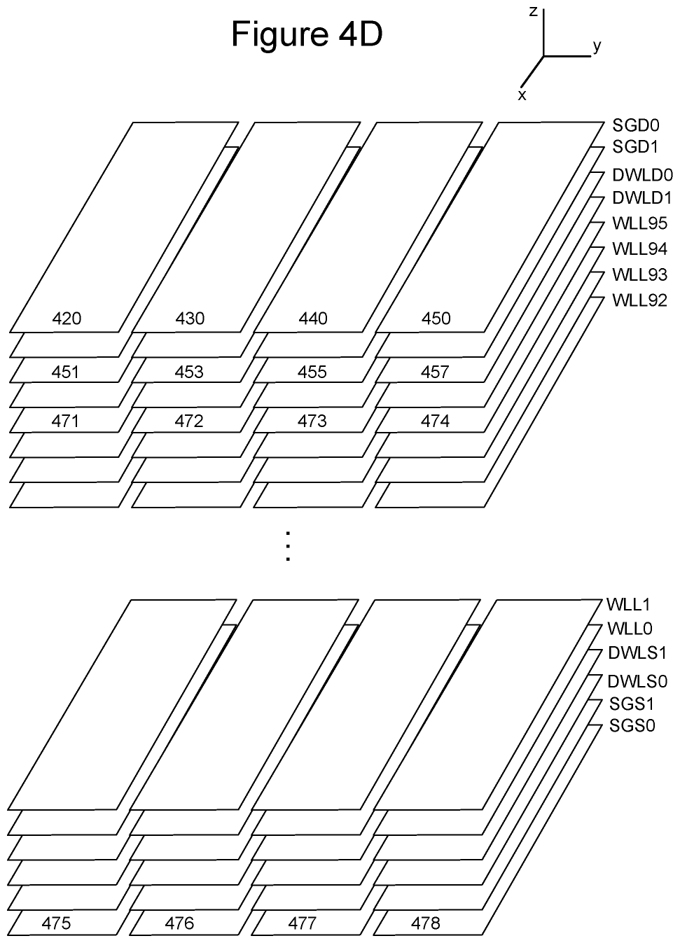

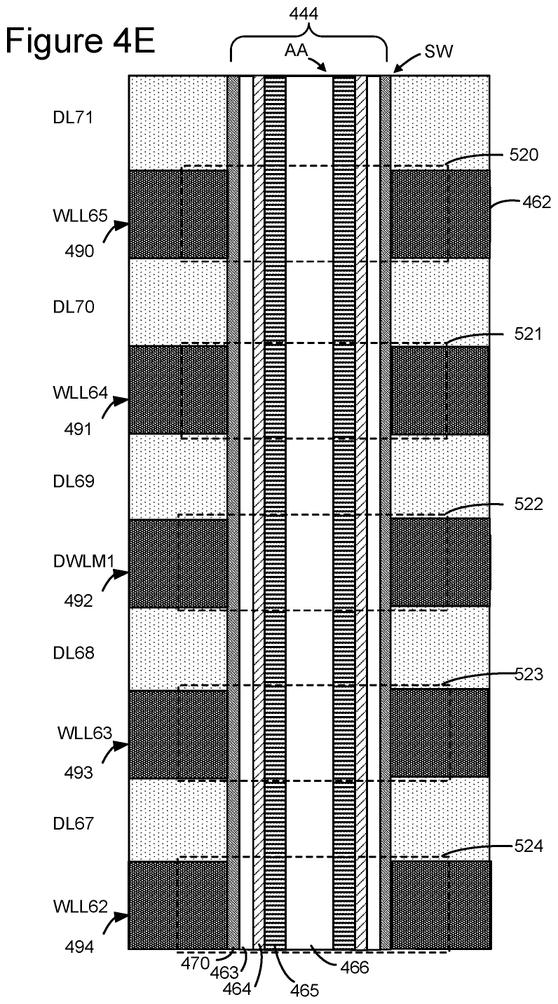

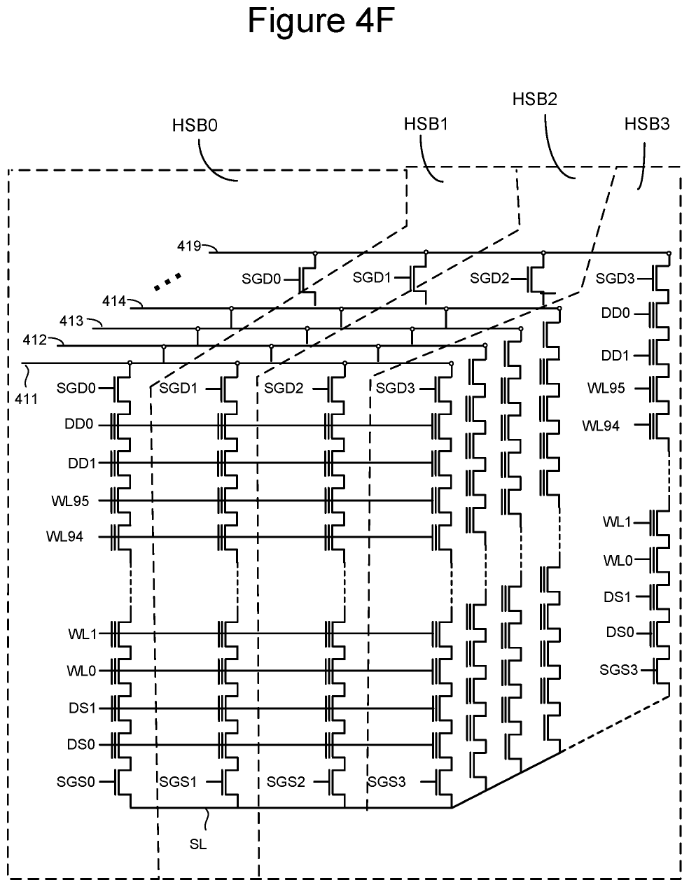

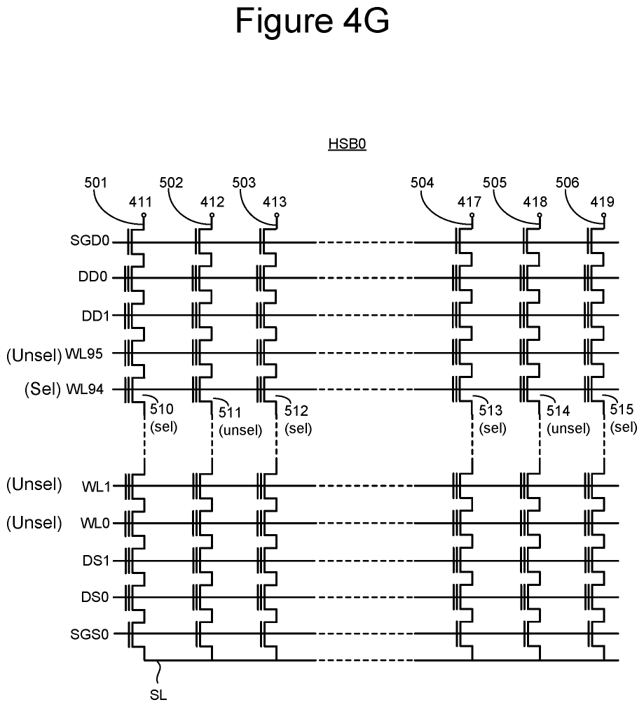

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201. For example, one or more temperature transducer may be provided in memory structure die 201 and may be connected to system control logic 260 in control die 211 so that system control logic 260 may use temperature measurement values obtained from such temperature transducer(s) to adjust operating parameters according to temperature as appropriate. Temperature transducers may also or alternatively be provided in control die 211 and/or memory controller 120.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 211.

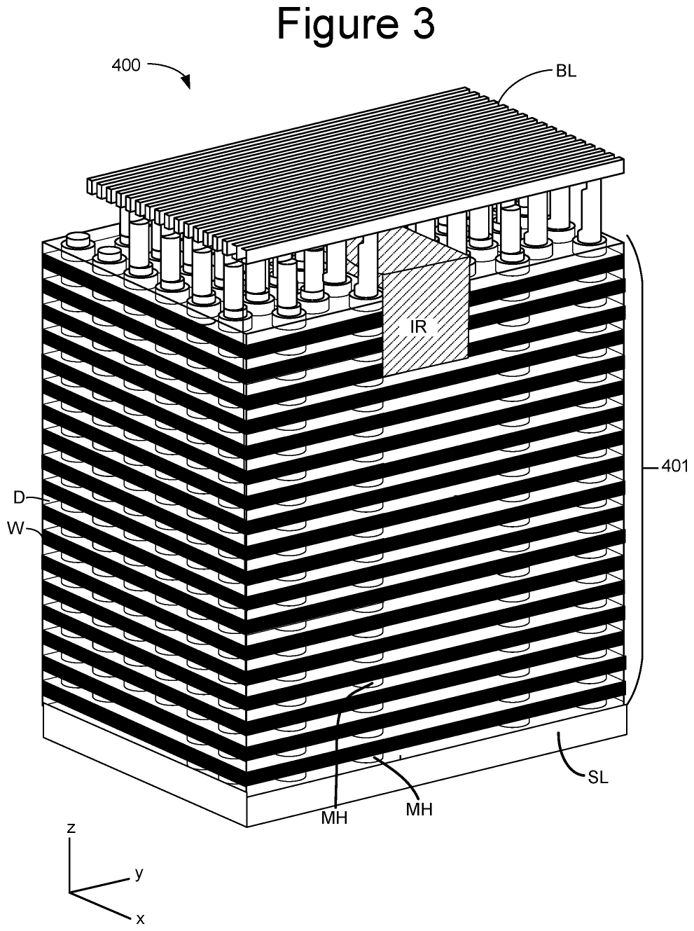

FIG. 3 is a perspective view of a portion of one example embodiment of a monolithic three dimensional memory array/structure that can comprise memory structure 202, which includes a plurality non-volatile memory cells arranged as vertical NAND strings. For example, FIG. 3 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 3 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

FIG. 4A is a block diagram explaining one example organization of memory structure 202, which is divided into two planes 302 and 304. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, memory cells can be grouped into blocks for other reasons, such as to organize the memory structure 202 to enable the signaling and selection circuits. In some embodiments, a block represents a groups of connected memory cells as the memory cells of a block share a common set of word lines.

FIGS. 4B-4F depict an example three dimensional (“3D”) NAND structure that corresponds to the structure of FIG. 3 and can be used to implement memory structure 202 of FIG. 2A or 2B. FIG. 4B is a block diagram depicting a top view of a portion of one block from memory structure 202. The portion of the block depicted in FIG. 4B corresponds to portion 306 in block 2 of FIG. 4A. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends beyond the portion shown, the block includes more vertical columns than depicted in FIG. 4B.

FIG. 4B also depicts a set of bit lines 415, including bit lines 411, 412, 413, 414, 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy word line layers DWLD0, DWLD1, DWLM1, DWLM0, DWLS0 and DWLS1 are provided, in addition to the data word line layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106.

Columns 432, 434 of memory cells are depicted in the multi-layer stack. The stack includes a substrate 303, an insulating film 250 on the substrate, and a portion of a source line SL. A portion of the bit line 414 is also depicted. Note that NAND string 484 is connected to the bit line 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bit line 414. The local interconnects 404 and 406 from FIG. 4B are also depicted.

The stack 435 is divided into three vertical sub-blocks (VSB0, VSB1, VSB2). Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy word line layer DMLM0 is between vertical sub-block VSB0 and vertical sub-block VSB1. Dummy word line layer DMLM1 is between vertical sub-block VSB1 and vertical sub-block VSB2. The dummy word line layers have dummy memory cell transistors that may be used to electrically isolate a first set of memory cell transistors within the memory string (e.g., corresponding with vertical sub-block VSB0 word lines WLL0-WLL31) from a second set of memory cell transistors within the memory string (e.g., corresponding with the vertical sub-block VSB1 word lines WLL32-WLL63) during a memory operation (e.g., an erase operation or a programming operation).

FIG. 4D depicts an alternative view of the SG layers and word line layers of the stack 435 of FIG. 4C. The SGD layers SGD0 and SGD0 (the drain-side SG layers) each includes parallel rows of SG lines associated with the drain-side of a set of NAND strings. For example, SGD0 includes drain-side SG regions 420, 430, 440 and 450, consistent with FIG. 4B.

Below the SGD layers are the drain-side dummy word line layers. Each dummy word line layer represents a word line, in one approach, and is connected to a set of dummy memory cells at a given height in the stack. For example, DWLD0 comprises word line layer regions 451, 453, 455 and 457. A dummy memory cell, also referred to as a non-data memory cell, does not store data and is ineligible to store data, while a data memory cell is eligible to store data. Moreover, the Vth of a dummy memory cell is generally fixed at the time of manufacture or may be periodically adjusted, while the Vth of the data memory cells changes more frequently, e.g., during erase and programming operations of the data memory cells.

Below the dummy word line layers are the data word line layers. For example, WLL95 comprises word line layer regions 471, 472, 473 and 474.

Below the data word line layers are the source-side dummy word line layers.

Below the source-side dummy word line layers are the SGS layers. The SGS layers SGS0 and SGS1 (the source-side SG layers) each includes parallel rows of SG lines associated with the source-side of a set of NAND strings. For example, SGS0 includes source-side SG lines 475, 476, 477 and 478. Each SG line can be independently controlled, in one approach. Or the SG lines can be connected and commonly controlled.

FIG. 4E depicts a view of the region 445 of FIG. 4C. Data memory cell transistors 520 and 521 are above dummy memory cell transistor 522. Below dummy memory cell transistor 522 are data memory cell transistors 523 and 524. A number of layers can be deposited along the sidewall (SW) of the memory hole 444 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Non-data transistors (e.g., select transistors, dummy memory cell transistors) may also include the charge trapping layer 463. In FIG. 4E, dummy memory cell transistor 522 includes the charge trapping layer 463. Thus, the threshold voltage of at least some non-data transistors may also be adjusted by storing or removing electrons from the charge trapping layer 463. It is not required that all non-data transistors have an adjustable Vth. For example, the charge trapping layer 463 is not required to be present in every select transistor.

Each of the memory holes can be filled with a plurality of annular layers comprising a blocking oxide layer, a charge trapping layer, a tunneling layer and a channel layer. A core region of each of the memory holes is filled with a body material, and the plurality of annular layers are between the core region and the WLLs in each of the memory holes.

In some cases, the tunneling layer 464 can comprise multiple layers such as in an oxide-nitride-oxide configuration.

FIG. 4F is a schematic diagram of a portion of the memory depicted in in FIGS. 3-4E. FIG. 4F shows physical word lines WLL0-WLL95 running across the entire block. The structure of FIG. 4F corresponds to portion 306 in Block 2 of FIGS. 4A-E, including bit lines 411, 412, 413, 414, . . . 419. Within the block, each bit line is connected to four NAND strings. Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line. The block can also be thought of as divided into four horizontal sub-blocks HSB0, HSB1, HSB2 and HSB3. Horizontal sub-block HSB0 corresponds to those vertical NAND strings controlled by SGD0 and SGS0, Horizontal sub-block HSB1 corresponds to those vertical NAND strings controlled by SGD1 and SGS1, Horizontal sub-block HSB2 corresponds to those vertical NAND strings controlled by SGD2 and SGS2, and Horizontal sub-block HSB3 corresponds to those vertical NAND strings controlled by SGD3 and SGS3.

FIG. 4G is a schematic of horizontal sub-block HSB0. Horizontal sub-blocks HSB1, HSB2 and HSB3 have similar structures. FIG. 4G shows physical word lines WL0-WL95 running across the entire sub-block S0. All of the NAND strings of sub-block S0 are connected to SGD0 and SGS0. FIG. 4G only depicts six NAND stings 501, 502, 503, 504, 505 and 506; however, horizontal sub-block HSB0 will have thousands of NAND strings (e.g., 15,000 or more).

FIG. 4G is being used to explain the concept of a selected memory cell. A memory operation is an operation designed to use the memory for its purpose and includes one or more of reading data, writing/programming data, erasing memory cells, refreshing data in memory cells, and the like. During any given memory operation, a subset of the memory cells will be identified to be subjected to one or more parts of the memory operation. These memory cells identified to be subjected to the memory operation are referred to as selected memory cells. Memory cells that have not been identified to be subjected to the memory operation are referred to as unselected memory cells. Depending on the memory architecture, the memory type, and the memory operation, unselected memory cells may be actively or passively excluded from being subjected to the memory operation.

As an example of selected memory cells and unselected memory cells, during a programming process, the set of memory cells intended to take on a new electrical characteristic (or other characteristic) to reflect a changed programming state are referred to as the selected memory cells while the memory cells that are not intended to take on a new electrical characteristic (or other characteristic) to reflect a changed programming state are referred to as the unselected memory cells. In certain situations, unselected memory cells may be connected to the same word line as selected memory cells. Unselected memory cells may also be connected to different word lines than selected memory cells. Similarly, during a reading process, the set of memory cells to be read are referred to as the selected memory cells while the memory cells that are not intended to be read are referred to as the unselected memory cells.

To better understand the concept of selected memory cells and unselected memory cells, assume a programming operation is to be performed and, for example purposes only, that word line WL94 and horizontal sub-block HSB0 are selected for programming (see FIG. 4G). That means that all of the memory cells connected to WL94 that are in horizontal sub-blocks HSB1, HSB2 and HSB3 (the other horizontal sub-blocks) are unselected memory cells. Some of the memory cells connected to WL94 in horizontal sub-block HSO are selected memory cells and some of the memory cells connected to WL94 in horizontal sub-block HSO are unselected memory cells depending on how the programming operation is performed and the data pattern being programmed. For example, those memory cells that are to remain in the erased state S0 will be unselected memory cells, because their programming state will not change in order to store the desired data pattern, while those memory cells that are intended to take on a new electrical characteristic (or other characteristic) to reflect a changed programming state (e.g., programmed to states S1-S7) are selected memory cells. Looking at FIG. 4G, assume for example purposes, that memory cells 511 and 514 (which are connected to word line WL94) are to remain in the erased state; therefore, memory cells 511 and 514 are unselected memory cells (labeled “unsel” in FIG. 4G). Additionally, assume for example purposes that memory cells 510, 512, 513 and 515 (which are connected to word line WL94) are to be programmed to any of the data states S1-S7; therefore, memory cells 510, 512, 513 and 515 are selected memory cells (labeled “sel” in FIG. 4G). While some memory cells along WL94 may be considered unselected memory cells because they are to remain in the erased state, WL94 may be considered as a “selected word line” in this scenario because selected memory cells 510, 512, 513 and 515 are connected to WL94 and are accessed via WL94.

Although the example memory system of FIGS. 3-4G is a three dimensional memory structure that includes vertical NAND strings with charge-trapping material, other (2D and 3D) memory structures can also be used with the technology described herein. Different operations for accessing data in non-volatile memory cells (e.g., read, program, program verify) that are described below may be applied to one or more of the example memory systems described above with respect to FIGS. 3-4G.

Typically, the program voltage applied to the control gates (via a selected word line) during a program operation is applied as a series of program pulses. Between program pulses are a set of verify pulses to perform verification. In many implementations, the magnitude of the program pulses is increased with each successive pulse by a predetermined step size.

In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. For example, when data is written to a set of memory cells, some of the memory cells will need to store data associated with an erased state so they will not be programmed. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming.

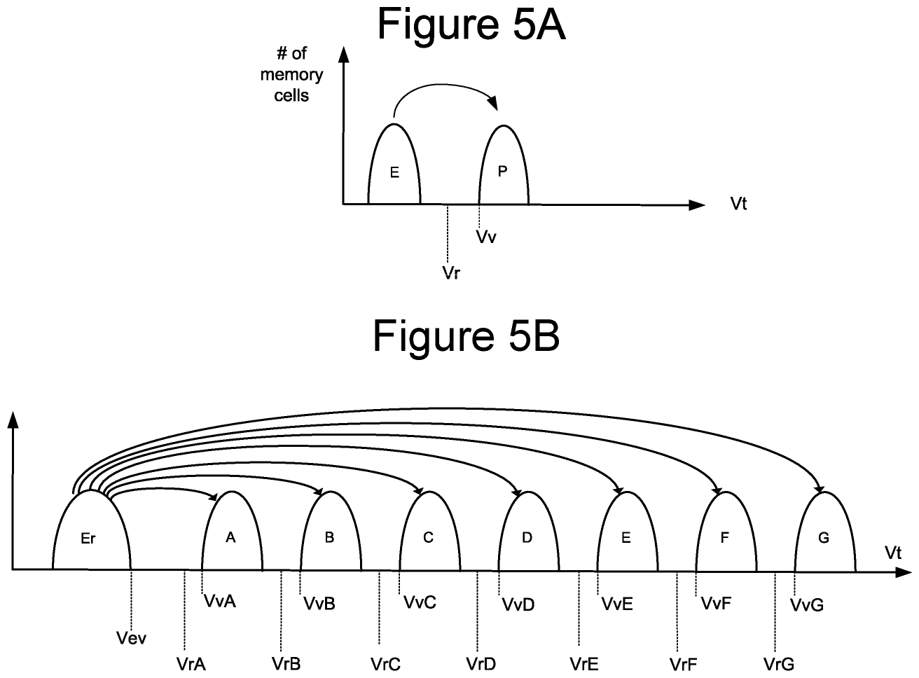

Memory cells in a memory system may be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, which illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv in a program-verify (or “verify”) operation. In some embodiments, verify is not performed during SLC programming.

Memory cells that are configured to store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores three bits of data. Other embodiments may use other data capacities per memory cell (e.g., such as two, four, or five bits of data per memory cell). Memory cells may be configured for SLC or MLC storage of data. In some cases, a block of nonvolatile memory cells may be configured for SLC data storage at one time and configured for MLC data storage at another time.

FIG. 5B shows eight threshold voltage distributions, corresponding to eight data states that stores three bits per cell. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. In an embodiment, the number of memory cells in each state is about the same.

FIG. 5B shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in. FIG. 5B also shows a number of verify reference voltages. The verify voltages are VvA, VvB, VvC, VvD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is inhibited (locked out) from further programming. Similar reasoning applies to the other data states. In some embodiments, verify is not performed during MLC programming.

While FIGS. 5A-B show threshold voltage distributions as distinct distributions that are separated from each other, real threshold voltage distributions may not be separated as shown (e.g., a distribution may partially overlap one or more neighboring distributions), which may make distinguishing different threshold voltage distributions more challenging. Also, threshold voltage distributions may not be identical across all nonvolatile memory cells of a memory die over time and under different conditions. Threshold voltage distributions may shift for a number of reasons including environmental reasons (e.g., temperature or other external parameter), leakage, effects of programming or erasing neighboring memory cells and effects of read operations on cells being read and/or neighboring cells, which may add to the difficulty of accurately distinguishing different threshold voltage distributions (e.g., when reading nonvolatile memory cells to determine corresponding data states). As the number of data states increases, the threshold voltage ranges for each data state become narrower which may increase overlap of neighboring distributions and provide additional challenges.

In some cases, undesirable overlap of neighboring distributions may be present at the time of programming due to the programming scheme used. Aspects of the present technology are directed to program operations that are configured to reduce such overlap and thereby reduce error rates of data programmed in nonvolatile memory cells. Aspects of the present technology are directed to technical solutions to problems associated with disturbance of programmed memory cells that may occur during a program operation.

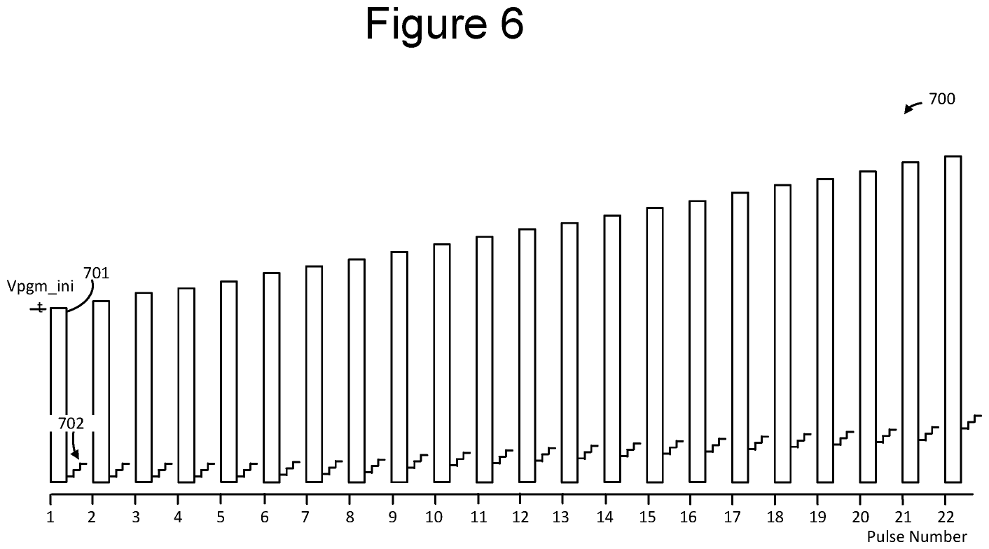

FIG. 6 depicts a voltage signal that includes a plurality of pulses applied to control gates of nonvolatile memory cells (e.g., applied to a word line) in an example program operation. The horizontal axis denotes a pulse number, ranging from 1-22, and the vertical axis denotes program voltage. During a program operation, program loops are performed for a selected word line in a selected block in each plane. A program loop comprises a program portion in which a program pulse at a corresponding program voltage is applied to the selected word line followed by a verify portion in which a verify signal is applied to the selected word line while one or more verify tests are performed for the associated memory cells. Other than the erased state, each assigned state has a verify voltage which is used in the verify test for the state in a program operation.

The voltage signal 700 includes a series of program pulses at different program voltages, including an initial program pulse 701, which are applied to a word line selected for programming. In this example, the voltage signal includes program pulses having corresponding program voltages which increase stepwise in amplitude program loops of a programming pass using a fixed or varying step size. This is referred to as incremental step pulse programming, where the program voltage starts with an initial program pulse 701 at an initial level Vpgm_int and increases in a step in each successive program loop, for instance, until the program operation is completed. A successful completion occurs when the threshold voltages of the selected memory cells reach the verify voltages of the assigned data states.

A program operation can include a single programming pass or multiple programming passes, where each pass uses incremental step pulse programming, for instance.

The verify signal in each program loop, including example verify signal 702, can include one or more verify voltages, based on the assigned data states which are being verified for the program loop. The verify tests can encompass lower assigned data states and then midrange assigned data states and then higher assigned data states as the program operations proceeds. The example verify signals depict three verify voltages as a simplification.

All memory cells may initially be in the erased state at the beginning of the program operation, for instance. After the program operation is completed, the data can be read from the memory cells using read voltages which are between the Vth distributions. At the same time, a read pass voltage, Vpass (e.g., 8-10 V), also referred to as pass voltage, is applied to the remaining word lines. By testing whether the Vth of a given memory cell is above or below one or more of the read reference voltages, the system can determine the data state which is represented by a memory cell. These voltages are demarcation voltages because they demarcate between Vth ranges of different data states.

Moreover, the data which is programmed or read can be arranged in pages. For example, with four data states, or two bits per cell, two logical pages of data can be stored together in a page. An example encoding of bits for the Er, A, B and C states is 11, 10, 00 and 01, respectively, in the format of upper page (UP) bit/lower page (LP) bit. A lower page read may use VrA and VrC and an upper page read may use VrB.

With eight data states, or three bits per cell, three pages of data can be stored. An example encoding of bits for the Er, A, B, C, D, E, F and G states is 111, 110, 100, 000, 010, 011, 001 and 101, respectively. Memories that store more than one bit per cell may be referred to as Multi-Level Cell (MLC) memory, which includes Three Level Cell (TLC) memory (storing three bits per cell using eight data states) and Quad Level Cell (QLC) memory (storing four bits per cell using sixteen data states). Memories that store one bit per cell using two data states may be referred to as Single Level Cell (SLC) memory.

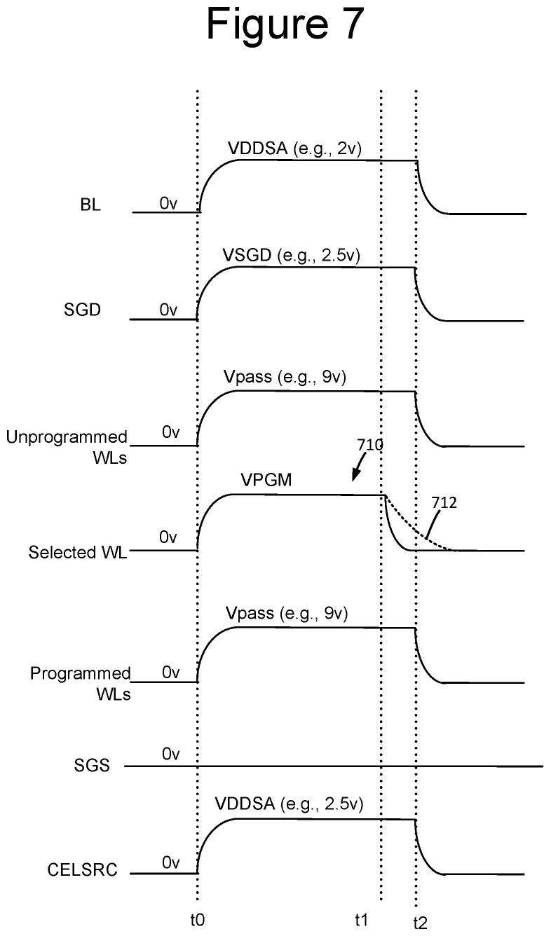

FIG. 7 shows an example of voltages on various component of a NAND structure (e.g., memory structure 202 as illustrated in the examples of FIGS. 3-4G) during a portion of a program operation (e.g., program operation illustrated in FIG. 6). FIG. 7 shows an example of a single program pulse 710 (e.g., any pulse of signal 700 shown in FIG. 6) and the voltages associated with applying program pulse 710. The horizontal axis represents time with each trace labeled according to the component on which the corresponding voltage is applied (voltage increasing in the vertical direction). At time to, voltages are ramped up from 0 volts to various target voltages. For example, bit line (“BL”) voltage ramps up from 0 volts to VDDSA (e.g., 2V). Select Gate Drain (“SGD”) voltage ramps up from 0 volts to VSGD (e.g., 2.5V) to turn SGD transistors on (conductive). Unprogrammed and programmed word line (“WL”) voltages ramp up from 0 volts to a pass voltage, Vpass (e.g., 9V), to make corresponding channels conductive. Selected WL voltage ramps up from 0 volts to a program voltage, VPGM for pulse 710 (e.g., Vpgm_int, or another program voltage shown in FIG. 6) to cause programming. Select Gate Source (“SGS”) voltage is maintained at 0 volts to maintain SGS transistors off (nonconductive). Source voltage (“CELSRC”) ramps up from 0 volts to VDDSA (e.g., 2.5 volts).

Subsequently, at time t1, the selected WL voltage ramps down from VPGM at the end of the program pulse, while other voltages remain at their previous levels. Subsequently, at time t2, other voltages including BL, SGD, unprogrammed and programmed WL and CELSRC voltages ramp down. A sufficient time difference between ramping down selected WL voltage from VPGM and ramping down other components (e.g., time difference t2-t1) may allow the selected WL to adequately discharge prior to cutting off channel conductivity (e.g., solid line shows discharge to 0 volts prior to t2). Failure to adequately discharge the selected WL prior to cutting off channel conductivity (e.g., as shown by slow discharge indicated by a dashed line 712) because of insufficient time t2-t1 or otherwise may have undesirable consequences. For example, inadequate discharge of a selected word line at the end of a program pulse may affect charge distribution in a charge trapping layer and thus affect data states that are read (e.g., data states may be disturbed and may result in errors or bad bits when subsequently read). The discharge characteristics of a given program pulse may depend on the location of the selected WL and the voltage being discharged. For example, higher voltages may take longer to discharge so that higher values of VPGM associated with higher data states (later pulses in signal 700) may be more subject inadequate discharge than lower values of VPGM associated with lower data states (earlier pulses in signal 700). Aspects of the present technology may be applied selectively to different program pulses (e.g., only program pulses with VPGM greater than a predetermined voltage).

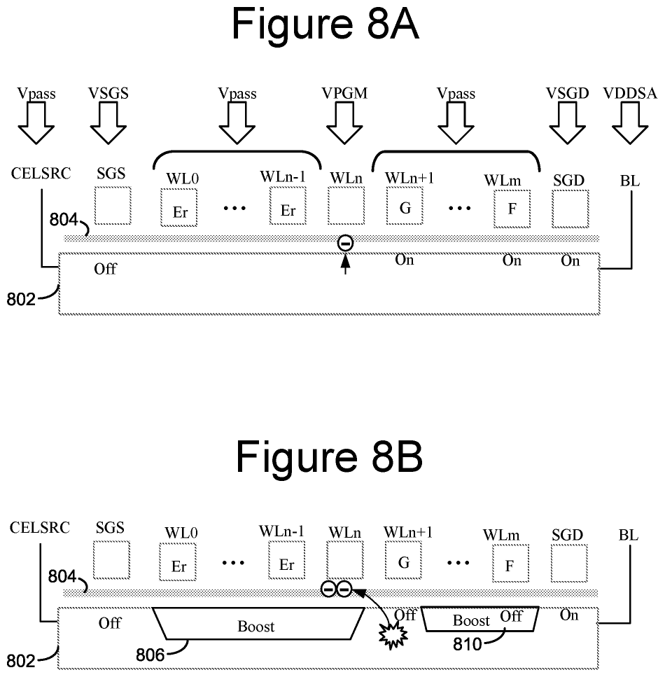

FIGS. 8A-B illustrate an example of channel cutoff resulting from inadequate discharge of a selected word line at the end of a program pulse (e.g., discharge illustrated by line 712). FIG. 8A shows channel region 802 of a NAND string formed by word lines WL0 to WLm and select gates SGS and SGD. In FIG. 8A, WLn is being programmed (e.g., WLn is the selected WL). FIG. 8A shows the voltages applied to different components during a program pulse (e.g., at a time between t0 and t1 in FIG. 7). While channel 802 is turned off at SGS (e.g., VSGS=0 volts), channel 802 is otherwise on, or electrically conductive (e.g., unselected memory cells are turned on by Vpass, SGD is turned on by VSGD and the selected memory cell is turned on by VPGM). Programming may occur at the time shown as the electric field between selected word line WLn and channel 802 causes electrons from channel 802 to move to charge-trapping layer 804 and become trapped there, which increases threshold voltage.

FIG. 8B shows the situation when channel cutoff occurs as voltages are ramped down (e.g., between t1 and t2). While SGD remains on, at least some memory cells along channel 802 may turn off as voltages applied on WLn+1 to WLm (word lines where programming has already occurred) ramp down. For example, a memory cell along WLn+1 is shown having data state G (a relatively high state associated with a high threshold voltage) so that it turns off earlier than some other programmed memory cells. Similarly, a memory cell along WLm is shown a having data stage F (a relatively high data state associated with high threshold voltage) so that it turns off earlier than some other programmed memory cells. Other memory cells (not shown) between WLn+1 and WLm that are programmed to lower stages (e.g., Er to E) may not turn off at this point because of their relatively low threshold voltages. Because programming proceeds from drain side to source side in this example (from WLm to WL0), memory cells along WL0 to WLn−1 remain in the erased state “Er” and remain on. SGS remains off so that channel 802 may be significantly boosted on the source side and under WLn as indicated by Boost region 806. Additional boosting may occur in Boost region 810 on the drain side of channel 802 where highly programmed memory cells (e.g., programmed to data states G and F) cause channel cutoff. In this situation, hot carrier injection may occur between selected word line WLn and its drain-side neighbor word line, WLn+1, which may cause electrons to be trapped in charge trapping layer 804, thereby disturbing the programmed data (e.g., additional electrons causing an increase in threshold voltage of a memory cell formed along selected word line WLn).

With programming starting from WLm, the channel cutoff pattern shown may not apply to programming WLm (e.g., no other word line on drain side of WLm) so that program pulse discharge problems may not occur when programming WLm. Program pulse discharge problems may increase as programming proceeds and the number of highly-programmed cells along NAND strings increases. Measures to mitigate program pulse discharge problems may be selectively applied to only word lines that experience or are likely to experience program pulse discharge problems (e.g., WLn as illustrated in FIGS. 8A-B) and may omit word lines that do not experience or are unlikely to experience such problems (e.g., WLm). Measures to mitigate program pulse discharge problems may be adapted to the severity of the discharge problems at a given location or for a given pulse.

The effects of inadequate program pulse discharge may vary from die-to-die, from block-to-block, from level-to-level and/or from word line-to-word line as a result of variation in devices at different locations (e.g., process variation across a wafer) or otherwise.

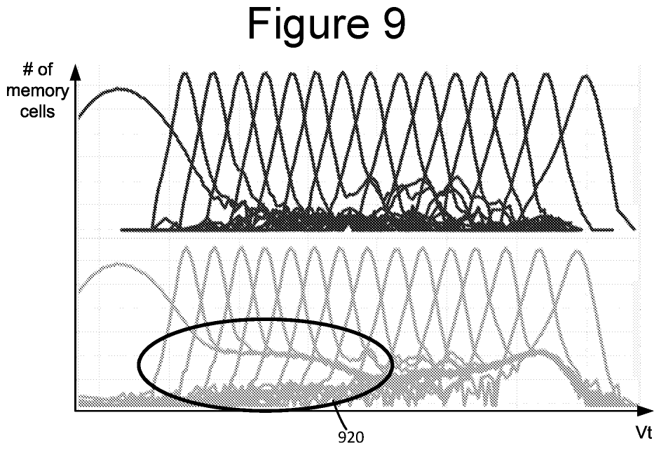

FIG. 9 illustrates an example that shows two plots of memory cell threshold voltages corresponding to memory cells programmed to sixteen data states (e.g., QLC memory storing four bits per cell). Unlike FIG. 5B, FIG. 9 shows significant overlap between threshold voltage distributions for different data states, which may result in significant numbers of bad bits when data is read. While a number of bad bits may be correctable by ECC, an increased number of bad bits may require increased ECC resources (e.g., stronger ECC, more powerful ECC engine, more time to perform ECC correction) and a number of bad bits above an ECC limit will result in data being uncorrectable by ECC (“UECC”). It is generally desirable to avoid excessive overlap between threshold voltage distributions, which could result in UECC data and/or excessive use of ECC resources.

The upper plot in FIG. 9 shows threshold voltage (Vt) distributions for nonvolatile memory cells of a first (good) die, with threshold voltage distributions having an acceptable amount of overlap that may correspond to a number of bad bits that is correctable by ECC within an acceptable time. The lower plot shows threshold voltage distributions for nonvolatile memory cells of a second die, with threshold voltage distributions having an unacceptable amount of overlap that may correspond to an excessive number of bad bits that may be UECC or uncorrectable within an acceptable time. For example, the circled area 920 shows significantly more overlap between adjacent data states which may be due to channel cutoff caused by inadequate program pulse discharge (e.g., mechanism illustrated in FIGS. 8A-B). Techniques described to address inadequate program pulse discharge may be selectively implemented in dies that have significant program pulse discharge problems (e.g., as illustrated in the lower plot) and/or may be selectively applied within individual dies on a block-by-block basis and/or word line-by-word line and/or other basis. Techniques described to address inadequate program pulse discharge may also be selectively implemented for certain program pulses and not others as discussed above.

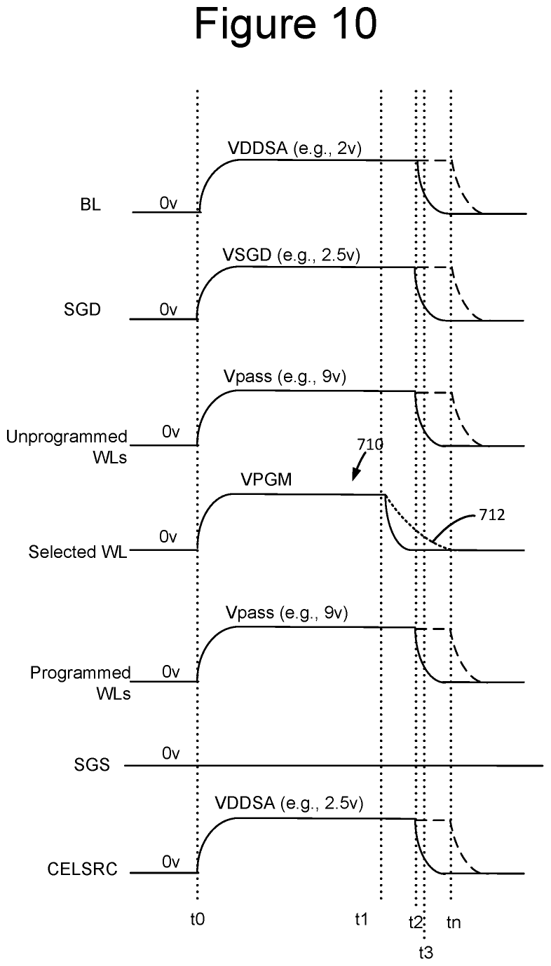

FIG. 10 shows mitigating disturbance caused by channel cutoff that may result from inadequate program voltage discharge according to an example of the present technology. While FIG. 7 showed an example in which the delay time between initiating discharge of the selected WL (t1) and initiating discharge of other components (e.g., unselected WLs, SGD, CELSRC and BL) was a fixed time (t2-t1) for all program pulses across all word lines or memory cells, FIG. 10 illustrates an example in which different delay times are used. For example, while some program pulses on some selected word lines may discharge adequately in time t2-t1, other pulses may not discharge adequately by time t2 but may discharge adequately by t3, which is after t2 (e.g., using delay time that is offset by t3-t2). Other pulses may not discharge adequately by time t3 but may discharge adequately by some time later up to tn (e.g., t4, t5, t6 . . . tn). For example, dashed lines show discharge of unselected WLs, SGD, CELSRC and BL initiated at time tn, giving a delay time, tn-t1, that is offset by tn-t2 (compared with t2-t1) for discharge of the selected WL prior to initiation. In the example shown, n−1 different delay times may be applied between initiating discharge of a program pulse from VPGM and initiating discharge of other components (e.g., unselected WLs, SGD, CELSRC and BL) where delay times (or offsets from a reference delay time such as t2-t1) may be selected according to VPGM (e.g., longer offset giving longer delay time for higher VPGM voltage), on a die-by-die basis, block-by-block basis, word line-by-word line basis, or otherwise. By providing different offset times as shown, the benefits of adequate program voltage discharge (e.g., lower Bit Error Rate or BER) may be obtained without an excessive time penalty (e.g., selective application of longer times is more time-efficient than universally extending times).

Longer times may be used for particular program pulses (e.g., program pulses with VPGM above a predetermined voltage) and/or according to location (e.g., different dies, blocks, word lines or other). For example, program pulses above a first predetermined voltage may be discharged for a first time period before initiation of discharge of other components, program pulses above a second predetermined voltage may be discharged for a second time period before initiation of discharge of other components and so on (e.g., discharge of unselected WLs may be initiated at t2 where VPGM<V2, initiated at t3 where V2<VPGM<V3, initiated at t4 where V3<VPGM<V4 . . . initiated at tn where Vn−1<VPGM).

The different delay times to be used for different VPGM values may be obtained by testing a population of dies and may be configured as constant values across all similar dies. In some cases, testing may allow such times to be individually set on a die-by-die basis, block-by-block basis, word line-by-word line basis or otherwise. In some cases, times may be permanently set (e.g., fixed values throughout the lifetime of a product) while in other cases times may be changed during a product lifetime. For example, in response to reading data with increasing BER, reaching a predetermined number of write-erase cycles or in response to some other triggering event, control circuits in a data storage system may adjust delay times between initiating VPGM discharge and initiating discharge of other components (e.g., times may be increased to ensure adequate discharge of selected WLs).

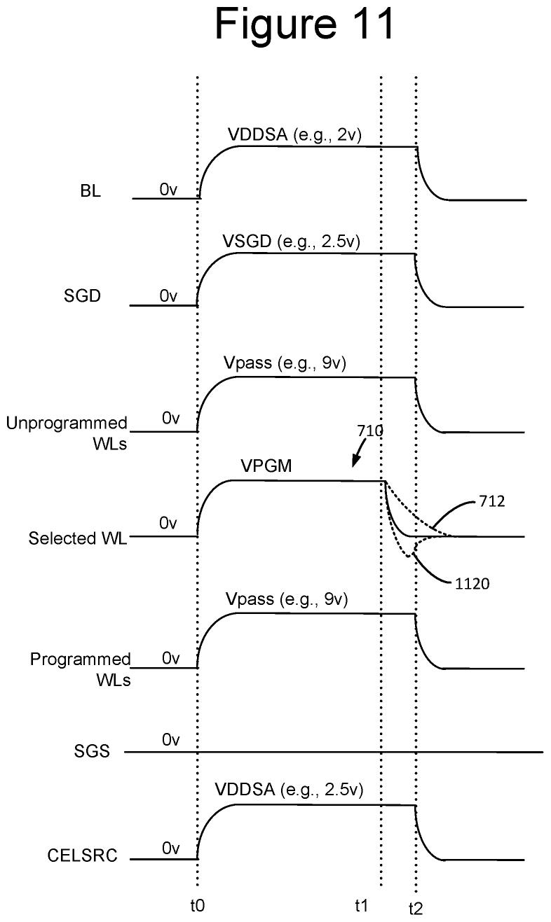

FIG. 11 shows mitigating disturbance caused by channel cutoff that may result from inadequate program voltage discharge according to an example of the present technology. While program pulses of previous examples showed discharge from VPGM to a setpoint that is equal to a post-pulse voltage (e.g., 0 volts in the illustrated examples), in some examples, discharge may be facilitated by using a setpoint that is less than the post-pulse voltage to ensure a fast ramp-down and provide a “kick” in selected word line voltage. A kick below the subsequent voltage may be referred to as a “negative kick” even if the voltage remains above zero volts throughout the negative kick (e.g., “negative” in the context of “negative kick” does not necessarily indicate negative in absolute terms but instead indicates the direction of the kick below the previous and/or subsequent voltage(s)).

FIG. 11 includes voltage trace 1120 showing an example of a negative kick that brings the voltage on the selected WL below the post-pulse voltage (0 volts in this example) to enable fast ramp-down of the selected WL so that at time t2, the selected WL is adequately discharged (e.g., discharged to at least a sufficient voltage so that resulting electric fields in the region near the selected WL are insufficient to cause significant numbers of electrons to enter a charge-trapping layer as shown in FIG. 8B). Subsequent to a negative kick, a voltage setpoint for the selected WL may be set to the post-pulse voltage (0 volts in the example shown). WL driver circuits (e.g., array driver 224) and/or coupling with other array components may bring the voltage on the selected WL to the post-pulse voltage.

Fast ramp-down using a negative kick voltage may be selectively applied. For example, according to VPGM (selectively used for pulses having VPGM greater than a predetermined voltage) and/or location (e.g., die, block, word line or other location). Furthermore, negative kick voltages are not necessarily uniform. A memory system may apply different negative kick voltages according to factors such as VPGM and/or location.

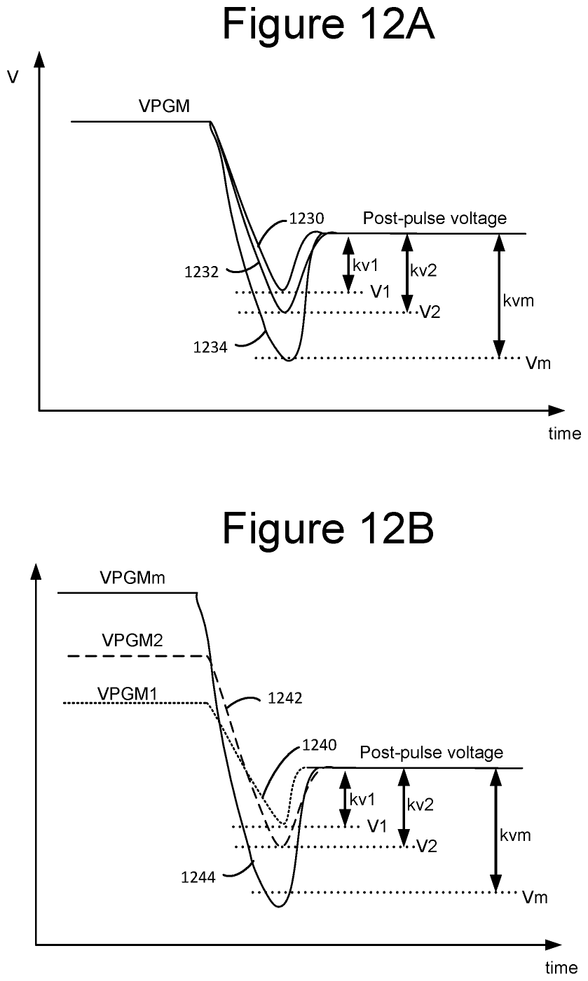

FIG. 12A illustrates different negative kick voltages that may be applied to selected word lines at the end of a program pulse. A first trace 1230 shows an example of fast ramp-down from VPGM to a first offset target voltage, V1, that is offset from the post-pulse voltage by a first negative kick voltage, kv1. A second trace 1232 shows an example of fast ramp-down from VPGM to a second offset target voltage, V2, that is offset from the post-pulse voltage by a second negative kick voltage, kv2. Additional offset target voltages (e.g., V3, V4, V5 and so on) and corresponding kick voltages (e.g., kv3, kv4, kv5 and so on) may be provided up to a last offset target voltage, Vm, that is offset from the post-pulse voltage by an m^{th} negative kick voltage, kvm.

The number (e.g., value of m) and magnitudes of offset target voltages and corresponding negative kick voltages may be determined by testing a population of dies and may be configured as constant values across all similar dies. In some cases, testing may allow negative kick voltages to be individually set on a die-by-die basis, block-by-block basis, word line-by-word line basis or otherwise. In some cases, voltages may be permanently set (e.g., fixed values throughout the lifetime of a product) while in other cases negative kick voltages may be changed during a product lifetime. For example, in response to reading data with increasing BER, reaching a predetermined number of write-erase cycles or in response to some other triggering event, control circuits in a data storage system may adjust negative kick voltages (e.g., kick voltages may be increased to ensure adequate discharge of selected WLs).

While FIG. 12A shows all negative kick voltages applied to a program pulse of the same magnitude (VPGM is a single value), in an example, different negative kick voltages are applied for different VPGM values. For example, the magnitude of a negative kick voltage may increase with increasing VPGM. For some lower values of VPGM (e.g., for lower data states) no negative kick may be needed. At the end of a pulse with VPGM above a first predetermined voltage, a first negative kick voltage may be applied, while at the end of a pulse with VPGM above a second predetermined voltage that is greater than the first predetermined voltage, a second negative kick voltage may be applied that is greater than the first negative kick voltage.

FIG. 12B shows an example in which different negative kick voltages are applied according to VPGM with the magnitude of the negative kick voltage increasing with increasing VPGM. A first trace 1240 shows an example of fast ramp-down from VPGM1 to a first offset target voltage, V1, that is offset from the post-pulse voltage by a first negative kick voltage, kv1. A second trace 1242 shows an example of fast ramp-down from VPGM2, which is higher than VPGM1, to a second offset target voltage, V2, that is offset from the post-pulse voltage by a second negative kick voltage, kv2, which is greater than kv1. Additional offset target voltages (e.g., V3, V4, V5 and so on) and corresponding kick voltages (e.g., kv3, kv4, kv5 and so on) may be provided up to a last offset target voltage, Vm, that is offset from the post-pulse voltage by an m^{th} negative kick voltage, kVm, and is applied to a pulse of magnitude VPGMm, which is greater than VPGM2 (e.g., control circuits increase the magnitude of the negative kick voltage from a first magnitude, kV1, for a predetermined pulse to a last magnitude, kVm, for a last pulse of a set of program pulses). While not shown in FIG. 12B, additional program pulses of magnitude less than VPGM1 may not end in a negative voltage kick (e.g., such pulses may be adequately discharged without a negative kick).

While FIG. 11 shows different times without negative kick voltages and FIGS. 12A-B show different kick voltages without showing different times (e.g., two techniques applied separately), examples of the present technology may apply both techniques in a single memory system (e.g., the time of discharge of unselected word lines and the magnitude of a negative kick voltage on a selected word line may both be controlled to mitigate or eliminate problems associated with insufficient discharge of selected WLs at the end of program pulses.

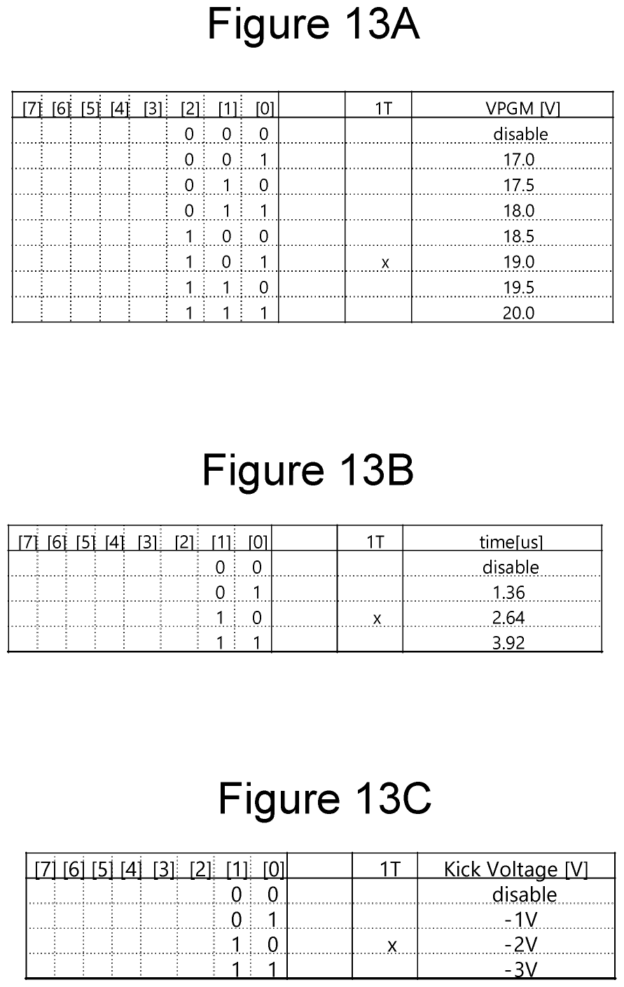

FIGS. 13A-C illustrate examples of applying aspects of the present technology in a nonvolatile memory. FIG. 13A shows a table that includes three-digit codes for certain values of VPGM (e.g., for higher values of VPGM that may be used to program nonvolatile memory cells to higher threshold voltages). A first code, 000, may be used for all voltages not shown in the table (e.g., VPGM<17.0 volts), code 001 corresponds to VPGM=17.0, code 010 corresponds to VPGM=17.5, code 011 corresponds to VPGM=18.0 and so on to code 111, which corresponds to VPGM=20.0 (e.g., the highest VPGM used in the memory array). The codes may facilitate applying different techniques to mitigate inadequate discharge of program pulses (e.g., different delay time offsets and/or negative kick voltages and/or other techniques). For any value of VPGM corresponding to code 000, such techniques may be disabled (e.g., pulses with VPGM<17.0 volts may adequately discharge without applying techniques described above).

FIG. 13B shows a table that includes a two digit code and a time offset to be applied to a delay time between initiating discharge of a selected WL and initiation of discharge of other components (e.g., unselected WLs) to provide different delay times. The delay times may correspond to the different times illustrated in FIG. 10 (e.g., with n=5). The time offsets may be with respect to a reference time (e.g., t2-t1) or default time. The two digit code may correspond to the first two digits shown in the table of FIG. 13A so that, pulses having VPGM=17.0 volts and VPGM <17.0 volts (code 00) have delay offset times disabled. Pulses having VPGM=17.5 or 18.0 volts (code 01) apply an offset time of 1.36 us (e.g., t3-t2=1.36 us). Pulses having VPGM=18.5 or 19 volts (code 10) apply an offset time of 2.64 us (e.g., t4-t2=2.64 us). Pulses having VPGM=19.5 or 20.0 volts (code 11) apply an offset of 3.92 us (e.g., t5-t2=3.92 us). In other examples, delay offset times may be applied only for pulses above a predetermined voltage that may be between 18.5 volts and 19.5 volts (e.g., predetermined voltage=19.0 volts).

FIG. 13C shows a table that includes a two digit code and a kick voltage to be applied to a voltage setpoint used to cause fast ramp-down from VPGM at the end of a program pulse. The kick voltages may correspond to the different kick voltages shown in FIG. 12A-B (e.g., with m=3). The two digit code may correspond to the first two digits shown in the table of FIG. 13A so that, pulses having VPGM=17.0 volts and VPGM<17.0 volts (code 00) have kick voltage disabled (e.g., fast ramp-down may apply to only program pulses having VPGM of 17.5 volts and higher or later). Pulses having VPGM=17.5 or 18.0 volts (code 01) apply a kick voltage of −1 volts. Pulses having VPGM=18.5 or 19 volts (code 10) apply a kick voltage of −2 volts. Pulses having VPGM=19.5 or 20.0 volts (code 11) apply a kick voltage of −3 volts.

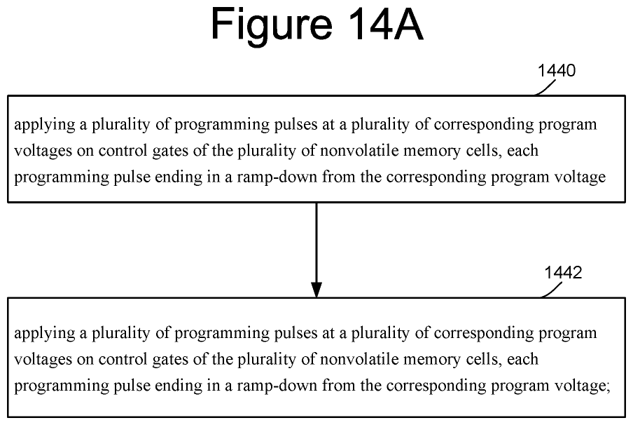

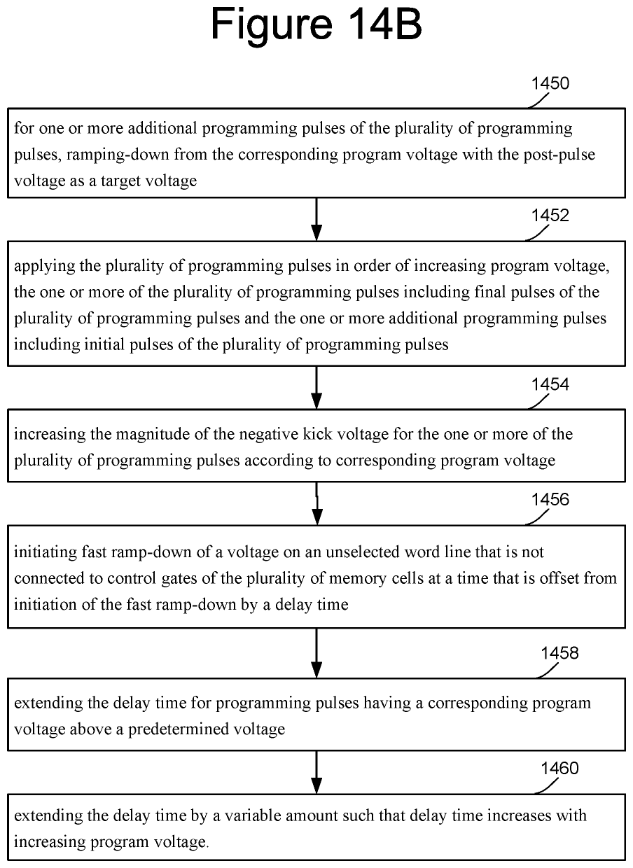

FIG. 14 illustrates an example of a method illustrating aspects of the present technology. The method includes applying a plurality of program pulses at a plurality of corresponding program voltages on control gates of the plurality of nonvolatile memory cells, each program pulse ending in a ramp-down from the corresponding program voltage 1440 and for one or more of the plurality of program pulses, ramping-down from the corresponding program voltage to a target voltage that is offset from a post-pulse voltage by a negative kick voltage 1442 (e.g., negative kick voltages illustrated in FIGS. 12A-B).

FIG. 14B illustrates various additional, optional steps including for one or more additional program pulses of the plurality of program pulses, ramping-down from the corresponding program voltage with the post-pulse voltage as a target voltage 1450 and (e.g., offset disabled), applying the plurality of program pulses in order of increasing program voltage, the one or more of the plurality of program pulses including final pulses of the plurality of program pulses and the one or more additional program pulses including initial pulses of the plurality of program pulses 1452 (e.g., disable offset for earlier, lower VPGM pulses and enable for later, higher VPGM pulses). The optional steps also include increasing the magnitude of the negative kick voltage for the one or more of the plurality of program pulses according to corresponding program voltage 1454 (e.g., as shown in FIG. 12B), initiating fast ramp-down of a voltage on an unselected word line that is not connected to control gates of the plurality of memory cells at a time that is offset from initiation of the fast ramp-down by a delay time 1456 and extending the delay time for program pulses having a corresponding program voltage above a predetermined voltage 1458 (e.g., as shown in FIGS. 10 and 13B). The delay time may be a variable amount such that delay time increases with increasing program voltage 1460.

According to examples of the present technology, an apparatus includes control circuits configured to connect to nonvolatile memory cells. The control circuits are configured to program the plurality of nonvolatile memory cells by applying program pulses at corresponding program voltages on control gates of the nonvolatile memory cells. One or more of the program pulses ends in a fast ramp-down from the corresponding program voltage to an offset target voltage that is offset from a post-pulse voltage by a negative kick voltage.

In one or more embodiments, the one or more control circuits are further configured to selectively apply the fast ramp-down such that one or more of the plurality of program pulses ends in a ramp-down from the corresponding program voltage with the post-pulse voltage as a target voltage.

In one or more embodiments, the one or more control circuits are further configured to selectively apply the fast ramp-down only with program pulses having a corresponding program voltage above a predetermined voltage.

In one or more embodiments, the one or more control circuits are further configured to adjust the magnitude of the negative kick voltage according to the corresponding program voltage above the predetermined voltage such that the magnitude of the negative kick voltage increases with increasing program voltage.

In one or more embodiments, the plurality of corresponding program voltages range up to 20 volts and the predetermined voltage is between 18.5 volts and 19.5 volts.

In one or more embodiments, the one or more control circuits are further configured to initiate ramp-down of a voltage on an unselected word line that is not connected to control gates of the plurality of memory cells at a time that is offset from initiation of the fast ramp-down by a delay time.

In one or more embodiments, the one or more control circuits are further configured to selectively extend the delay time according to the corresponding program voltage.

In one or more embodiments, the one or more control circuits are further configured to extend the delay time according to the corresponding program voltage such that delay time increases with increasing program voltage above a predetermined voltage.

In one or more embodiments, the one or more control circuits are further configured to apply the plurality of program pulses at the plurality of corresponding program voltages in order of increasing program voltage and to apply the fast ramp-down to only program pulses from a predetermined pulse.

In one or more embodiments, the one or more control circuits are further configured to increase the magnitude of the negative kick voltage from a first magnitude for the predetermined pulse to a last magnitude for a last pulse of the plurality of program pulses.

In one or more embodiments, the one or more control circuits are further configured to initiate ramp-down of a voltage on an unselected word line that is not connected to control gates of the plurality of memory cells at a time that is offset from initiation of the fast ramp-down by a delay time and to extend the delay time for later pulses of the plurality of program pulses.

An example method of programming a plurality of memory cells includes applying a plurality of program pulses at a plurality of corresponding program voltages on control gates of the plurality of nonvolatile memory cells, each program pulse ending in a ramp-down from the corresponding program voltage; and for one or more of the plurality of program pulses, ramping-down from the corresponding program voltage to a target voltage that is offset from a post-pulse voltage by a negative kick voltage.

In one or more embodiments, the method further includes for one or more additional program pulses of the plurality of program pulses, ramping-down from the corresponding program voltage with the post-pulse voltage as a target voltage.

In one or more embodiments, the method further includes applying the plurality of program pulses in order of increasing program voltage, the one or more of the plurality of program pulses including final pulses of the plurality of program pulses and the one or more additional program pulses including initial pulses of the plurality of program pulses.

In one or more embodiments, the method further includes increasing the magnitude of the negative kick voltage for the one or more of the plurality of program pulses according to corresponding program voltage.

In one or more embodiments, the method further includes initiating fast ramp-down of a voltage on an unselected word line that is not connected to control gates of the plurality of memory cells at a time that is offset from initiation of the fast ramp-down by a delay time; and extending the delay time for program pulses having a corresponding program voltage above a predetermined voltage.

In one or more embodiments, the method further includes extending the delay time by a variable amount such that delay time increases with increasing program voltage.

An example storage system includes a plurality of nonvolatile memory cells arranged in NAND strings; and means for programming the plurality of nonvolatile memory cells by applying a plurality of program pulses at a plurality of corresponding program voltages on control gates of the plurality of nonvolatile memory cells, a first subset of the plurality of program pulses ending in a ramp-down from the corresponding program voltage to a post-pulse voltage and a second subset of the plurality of program pulses ending in a fast ramp-down from the corresponding program voltage to an offset target voltage that is offset from a post-pulse voltage by a negative kick voltage.

In one or more embodiments, the plurality of nonvolatile memory cells are located in a memory die; the means for programming is located in a control die; and the memory die is bonded to the control die to form an integrated memory assembly.

In one or more embodiments, the plurality of nonvolatile memory cells are arranged in a 3D NAND structure that includes a plurality of vertical NAND strings.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of nonvolatile memory cells, wherein the one or more control circuits are configured to:
program the plurality of nonvolatile memory cells by applying a plurality of program pulses at a plurality of corresponding program voltages on control gates of the plurality of nonvolatile memory cells, one or more of the plurality of program pulses ending in a fast ramp-down from the corresponding program voltage to an offset target voltage that is offset from a post-pulse voltage by a negative kick voltage.

2. The apparatus of claim 1, wherein the one or more control circuits are further configured to selectively apply the fast ramp-down such that one or more of the plurality of program pulses ends in a ramp-down from the corresponding program voltage with the post-pulse voltage as a target voltage.

3. The apparatus of claim 2, wherein the one or more control circuits are further configured to selectively apply the fast ramp-down only to program pulses having a corresponding program voltage above a predetermined voltage.

4. The apparatus of claim 3, wherein the one or more control circuits are further configured to adjust the magnitude of the negative kick voltage according to the corresponding program voltage above the predetermined voltage such that the magnitude of the negative kick voltage increases with increasing program voltage.

5. The apparatus of claim 3, wherein the plurality of corresponding program voltages range up to 20 volts and the predetermined voltage is between 18.5 volts and 19.5 volts.

6. The apparatus of claim 3, wherein the one or more control circuits are further configured to initiate ramp-down of a voltage on an unselected word line that is not connected to control gates of the plurality of memory cells at a time that is offset from initiation of the fast ramp-down by a delay time.

7. The apparatus of claim 6, wherein the one or more control circuits are further configured to selectively extend the delay time according to the corresponding program voltage.

8. The apparatus of claim 7, wherein the one or more control circuits are further configured to extend the delay time according to the corresponding program voltage such that delay time increases with increasing program voltage above a predetermined voltage.

9. The apparatus of claim 1, wherein the one or more control circuits are further configured to apply the plurality of program pulses at the plurality of corresponding program voltages in order of increasing program voltage and to apply the fast ramp-down to only program pulses from a predetermined pulse.

10. The apparatus of claim 9, wherein the one or more control circuits are further configured to increase the magnitude of the negative kick voltage from a first magnitude for the predetermined pulse to a last magnitude for a last pulse of the plurality of program pulses.

11. The apparatus of claim 10, wherein the one or more control circuits are further configured to initiate ramp-down of a voltage on an unselected word line that is not connected to control gates of the plurality of memory cells at a time that is offset from initiation of the fast ramp-down by a delay time and to extend the delay time for later pulses of the plurality of program pulses.

12. A method of programming a plurality of nonvolatile memory cells, comprising:
applying a plurality of program pulses at a plurality of corresponding program voltages on control gates of the plurality of nonvolatile memory cells, each program pulse ending in a ramp-down from the corresponding program voltage; and
for one or more of the plurality of program pulses, ramping-down from the corresponding program voltage to a target voltage that is offset from a post-pulse voltage by a negative kick voltage.

13. The method of claim 12, further comprising:
for one or more additional program pulses of the plurality of program pulses, ramping-down from the corresponding program voltage with the post-pulse voltage as a target voltage.

14. The method of claim 13, further comprising:
applying the plurality of program pulses in order of increasing program voltage, the one or more of the plurality of program pulses including final pulses of the plurality of program pulses and the one or more additional program pulses including initial pulses of the plurality of program pulses.

15. The method of claim 14, further comprising:
increasing the magnitude of the negative kick voltage for the one or more of the plurality of program pulses according to corresponding program voltage.

16. The method of claim 12, further comprising:
initiating fast ramp-down of a voltage on an unselected word line that is not connected to control gates of the plurality of memory cells at a time that is offset from initiation of the fast ramp-down by a delay time; and
extending the delay time for program pulses having a corresponding program voltage above a predetermined voltage.

17. The method of claim 16, further comprising:
extending the delay time by a variable amount such that delay time increases with increasing program voltage.

18. A storage system comprising:
a plurality of nonvolatile memory cells arranged in NAND strings; and
means for programming the plurality of nonvolatile memory cells by applying a plurality of program pulses at a plurality of corresponding program voltages on control gates of the plurality of nonvolatile memory cells, a first subset of the plurality of program pulses ending in a ramp-down from the corresponding program voltage to a post-pulse voltage and a second subset of the plurality of program pulses ending in a fast ramp-down from the corresponding program voltage to an offset target voltage that is offset from a post-pulse voltage by a negative kick voltage.

19. The storage system of claim 18 wherein:
the plurality of nonvolatile memory cells are located in a memory die;
the means for programming is located in a control die; and
the memory die is bonded to the control die to form an integrated memory assembly.

20. The storage system of claim 18, wherein the plurality of nonvolatile memory cells are arranged in a 3D NAND structure that includes a plurality of vertical NAND strings.
